(19) United States
(12) Patent Application Publication
(10) Pub. No.: US 2011/0058317 A1
(43) Pub. Date: Mar. 10, 2011

(54) HEIGHT ADJUSTING MECHANISM FOR ELECTRONIC DEVICE AND ELECTRONIC DEVICE PROVIDED WITH THE SAME

(76) Inventor: Yukihiko Oota, Tokyo (JP)

(21) Appl. No.: 12/736,719

(22) PCT Filed: May 19, 2008
(86) PCT No.: PCT/JP2008/059150

§ 371 Date: Nov. 3, 2010

(51) Int. Cl. H05K 7/00; F16M 11/24

(52) U.S. Cl. 361/679.01; 248/188.4

(57) ABSTRACT

A height adjusting mechanism (1) according to the present invention includes fixing portion (3a) having through hole (3b) formed therein, tapped member (2) having thread groove (12) formed thereon, wherein a rear side, which is the reverse side of a surface on which thread groove (12) is formed, covers at least a part of an inner wall surface of through hole (3b), and support leg (4) having screw rod (4a) formed with thread ridge (14) thereon in the longitudinal direction, screw rod (4a) being inserted into through hole (3b) such that thread groove (12) is in engaging relation with thread ridge (14), wherein fixing portion (3a) and tapped member (2) are engaged with each other to cause tapped member (2) to be fixed to fixing portion (3a) in the penetrating direction of through hole (3b) and in the radial direction of through hole (3b).

### TECHNICAL FIELD

The present invention relates to a height adjusting mechanism used for adjusting the height of an electronic device and an electronic device provided with the same.

### BACKGROUND ART

Some electronic devices, like a projector, for example, for projecting an image on the projection plane such as a screen, need to adjust their height when used. Such electronic devices are generally provided with height adjusting mechanisms having a support leg. Projectors provided with height adjusting mechanisms having a support leg can adjust image projecting positions by varying the length of the support leg to change the height to the surface on which the projector is placed or to change the angle of projection.

Some height adjusting mechanisms are called as “crew type”, the crew type height adjusting mechanisms have a support leg which has a screw rod inserted into a tapped hole formed on the bottom plate of the housing of an electronic device. The screw type height adjusting mechanism is configured such that a support leg is rotated in order to vary the amount of a screw rod inserted to the tapped hole for allowing the length of the support leg extending below the bottom surface of a housing to be changed.

FIG. 1 is a cross sectional view depicting a screw type height adjusting mechanism related to the invention of the present application, and FIG. 2 is an exploded perspective view depicting the height adjusting mechanism shown in FIG. 1.

Height adjusting mechanism 101 includes fixing portion 103a provided on housing 103 of an electronic device and having through hole 103b defined therein, tapped member 102 having tapped hole 102a therein and adapted to be fixed inside through hole 103b, and support leg 104 having screw rod 104a adapted to be inserted into tapped hole 102a in tapped member 102. Leg part 104b for supporting the electronic device is disposed at the lower end portion of screw rod 104a.

For height adjusting mechanism 101, support leg 104 is rotated in order to vary the amount of screw rod 104a inserted into tapped member 102 for allowing the length of support leg 104 extending below the bottom surface of housing 103 to be changed.

Housing 103 is made of a resin material for reducing the entire weight of the electronic device and production costs, and fixing portion 103a is formed in one piece with housing 103. On the other hand, screw rod 102 is made of a metal material.

For the screw type height adjusting mechanism, a metal screw rod is generally used. Because it is sometimes difficult for the metal screw rod to sufficiently mate with the tapped hole that is directly formed in the resin housing, a metal tapped member that is engaged with the screw rod is mounted in a through hole formed on the housing. For the tapped member, a metal nut or a metal plate formed with a tapped hole therein is used. The metal nut is fixed by being press-fit into the through hole formed on the housing and thermally welded thereto, whereas the metal plate formed with the tapped hole is fixed by being screwed to inner surface of the housing.

In height adjusting mechanism 101, a metal nut is used for tapped member 102. In mounting work, tapped member 102 is press-fit into through hole 103b in fixing portion 103a with a press-fit tool while being heated, and tapped member 102 is thermally welded to the inner wall surface of through hole 103a. Further, in height adjusting mechanism 101, because tapped member 102 is thermally welded to the inner wall surface of through hole 103a, it is necessary to use a tool or the like to remove tapped member 102 from housing 103 in disassembly operation for recycle. As described above, height adjusting mechanism 101 takes time and effort in mounting and dismounting work.

JP2007-173469A describes a height adjusting mechanism that solves these disadvantages. In this height adjusting mechanism, an elastically deformable engagement portion is provided in a tapped member, and the tapped member can be inserted into the through hole formed in the fixing portion in a state in which the engagement portion is elastically deformed. The tapped member inserted into the through hole is vertically fixed to the fixing portion by allowing the engagement portion to engage with the fixing portion. Furthermore, because the tapped member inserted into the through hole is formed so as to cover the entire circumference of the through hole with no clearance, the engagement portion of the tapped member is not removed from the fixing portion and is held in the through hole.

Consequently, in this height adjusting mechanism, in assembly operation, the tapped member is inserted into the through hole formed in the fixing portion by elastically deforming the engagement portion, and accordingly it is made possible to readily fix the tapped member to the fixing portion. In addition, in disassembly operation, the engagement of the engagement portion with the fixing portion is released by elastically deforming the engagement part, and consequently readily removing the tapped member fixed to the fixing portion from the fixing portion is made possible.

However, in the height adjusting mechanism described in JP2007-173469A, because a housing is made of a resin material, it is elastically deformed by an external impact or the like. Because the tapped member is not fixed to the fixing portion in the radial direction of the through hole, when the fixing portion in the housing is elastically deformed, a clearance can sometimes be created between the tapped member and the inner wall surface of the through hole. On this account, it can be considered that the engagement portion comes off from the fixing portion to cause the tapped member to fall off from the through hole.

### SUMMARY OF THE INVENTION

An object of the present invention is to provide a height adjusting mechanism that can facilitate operation to assemble and disassemble and that can stably support an electronic device.

A height adjusting mechanism according to the present invention includes a fixing portion having a through hole formed therein; a tapped member having a thread groove formed thereon, wherein a rear side, which is the reverse side of a surface on which the thread groove is formed, covers at least a part of an inner wall surface of the through hole; and a support leg having a screw rod formed with a thread ridge formed thereon in a longitudinal direction, the screw rod being inserted into the through hole such that the thread ridge is in engaging relation with the thread groove, wherein the fixing portion and the tapped member are engaged with each other to cause the tapped member to be fixed to the fixing portion in a penetrating direction of the through hole and in a radial direction of the through hole.

### BRIEF DESCRIPTION OF THE DRAWINGS

FIG. 1 is a cross sectional side view depicting a height adjusting mechanism related to the invention of the present application;

FIG. 2 is an exploded perspective view depicting the height adjusting mechanism shown in FIG. 1;

FIG. 3 is a cross sectional side view depicting a height adjusting mechanism according to a first embodiment of the present invention;

FIG. 4 shows perspective views depicting a tapped member of the height adjusting mechanism shown in FIG. 3;

FIG. 5 is an exploded perspective view depicting the height adjusting mechanism shown in FIG. 3; and

FIG. 6 is a side view depicting an electronic device according to a second embodiment of the present invention.

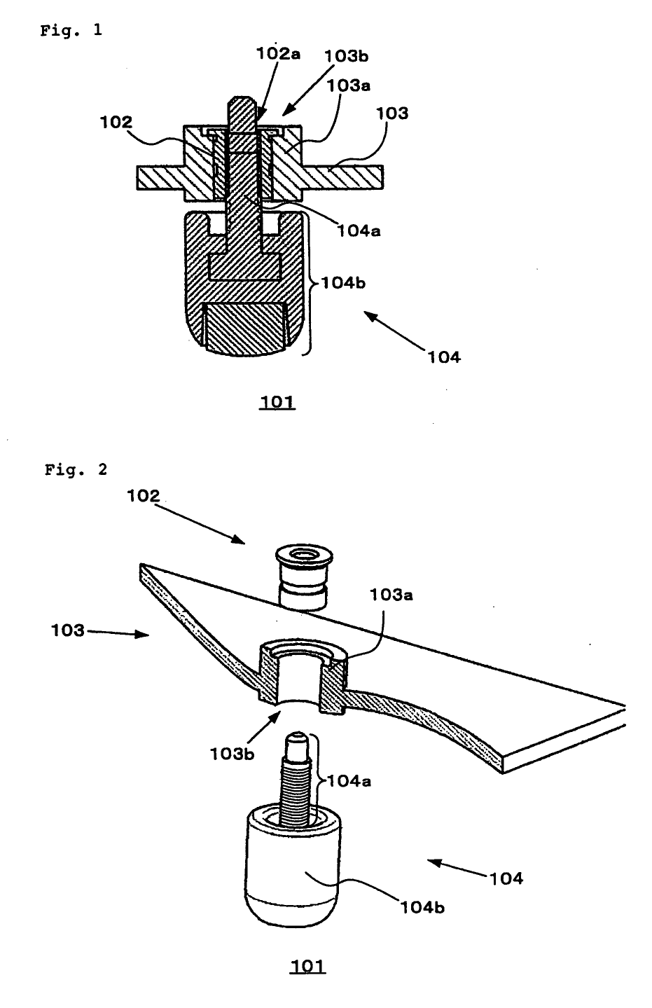

### BEST MODE FOR CARRYING OUT THE INVENTION

Next, embodiments of the present invention will be described with reference to the drawings.

### First embodiment

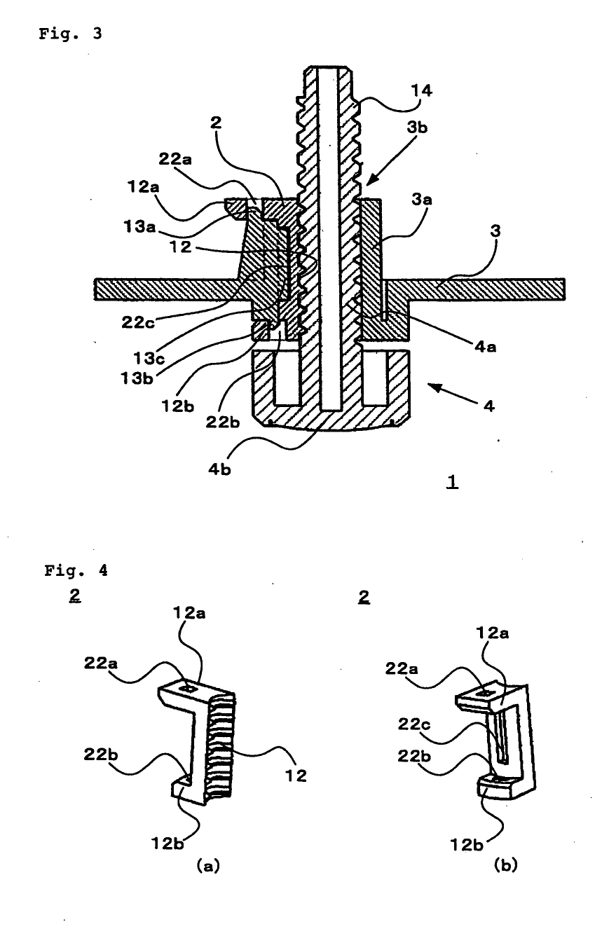

First, a height adjusting mechanism according to a first embodiment of the present invention will be described with reference to FIGS. 3 to 6. FIG. 3 is a cross sectional side view depicting the height adjusting mechanism according to the first embodiment of the present invention.

Height adjusting mechanism 1 includes fixing portion 3a that is disposed on housing 3 of an electronic device and that has through hole 3b formed therein, tapped member 2 that is mounted on fixing portion 3a so as to cover a part of the inner wall surface of through hole 3b, and support leg 4 that has screw rod 4a adapted to be inserted into through hole 3b in fixing portion 3a. Leg part 4b for supporting the electronic device is disposed at the lower end portion of screw rod 4a.

Fixing portion 3a is made of a resin material and formed in one piece with housing 3. Tapped member 2 is formed with thread groove 12 therein, and screw rod 4a is formed with thread ridge 14 in the longitudinal direction. A part of thread ridge 14 formed over the entire circumference of screw rod 4a and thread groove 12 formed inside tapped member 2 are engaged with each other to allow screw rod 4a to hold tapped member 2.

In height adjusting mechanism 1, support leg 4 is rotated in order to vary the amount of screw rod 4a inserted into through hole 3b, and consequently the length of the portion of support leg 4 extending below the bottom surface of housing 3 can be changed.

FIG. 4 shows perspective views depicting the tapped member of the height adjusting mechanism according to the embodiment. FIG. 4(a) shows tapped member 2 on thread groove 12 side, and FIG. 4(b) shows the rear side of tapped member 2, which is the reverse side of thread groove 12. At the upper and lower end portions of tapped member 2, engagement portions 12a and 12b extended to the rear side are disposed, respectively. First engagement holes 22a and 22b are respectively formed in engagement portions 12a and 12b. Further, second engagement hole 22c is formed on the rear side which opposite to the face on which thread groove 12 of tapped member 2 is formed.

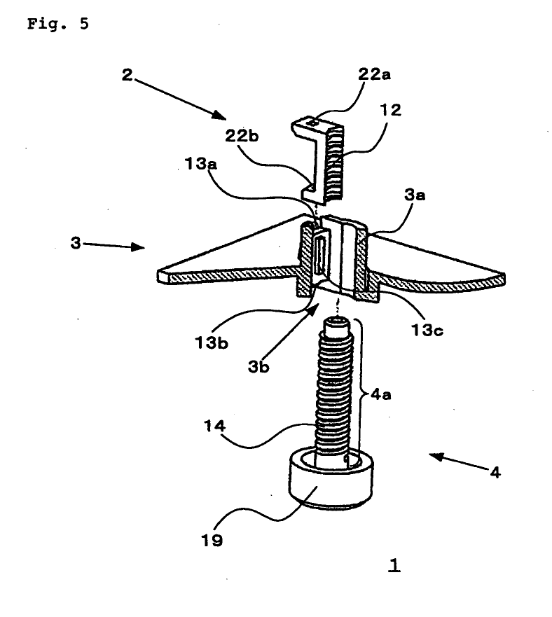

FIG. 5 is an exploded perspective view depicting the height adjusting mechanism according to the embodiment. FIG. 5 shows housing 3 is partially omitted. First projecting portions 13a and 13b are formed on the top surface and the under surface of fixing portion 3a in housing 3, respectively. Also, second projecting portion 13c is formed on the inner wall surface of through hole 3b in fixing portion 3a.

Tapped member 2 is mounted on fixing portion 3a such that the rear side covers a part of the inner wall surface of through hole 3b and engagement portion 12a and engagement portion 12b come into contact with the top surface and the under surface of fixing portion 3a, respectively. Consequently, in height adjusting mechanism 1, tapped member 2 is vertically fixed to fixing portion 3a.

Furthermore, in height adjusting mechanism 1, projecting portions 13a and 13b of fixing portion 3a and engagement holes 22a and 22b of tapped member 2 are engaged with each other, respectively, and projecting portions 13a and 13b of fixing portion 3a are then inserted into engagement holes 22a and 22b of tapped member 2, respectively, in the penetrating direction of through hole 3b. Consequently, tapped member 2 is fixed to fixing portion 3a also in the radial direction of through hole 3b.

In addition, in height adjusting mechanism 1, projecting portion 13c of fixing portion 3a and engagement hole 22c in tapped member 2 are engaged with each other, and projecting portion 13c on the inner wall surface of through hole 3b is then inserted into engagement hole 22c in tapped member 2 in the radial direction of through hole 3b. Accordingly, eliminating such an event in which tapped member 2 moves along the inner wall surface of through hole 3b is made possible. In this situation, such an event in which engagement portions 12a and 12b are elastically deformed to cause engagement holes 22a and 22b to come off from projecting portions 13a and 13b can be prevented. Additionally, because the load born from fixing portion 3a onto engagement portions 12a and 12b can be reduced, it also become possible to prevent engagement portions 12a and 12b from being damaged.

As described above, in height adjusting mechanism 1, even though housing 3 is elastically deformed due to an external impact or the like, the electronic device can be stably supported because engagement portions 12a and 12b do not tend to be removed from fixing portion 3a.

Further, in height adjusting mechanism 1, in assembly operation, engagement portion 12a and 12b are placed so as to come into contact with the top surface and the under surface of fixing portion 3a, respectively, and therefore, readily mounting tapped member 2 on fixing portion 3a becomes possible. Furthermore, in disassembly operation, the engagement of projecting portions 13a and 13b of fixing portion 3a with engagement holes 22a and 22b of tapped member 2 is released to readily remove tapped member 2 which has been mounted on fixing portion 3a from fixing portion 3a.

In typical height adjusting mechanisms, the tapped member is provided so as to cover the entire inner wall surface of the through hole in the fixing portion. However, in some cases, including the case of mounting the height adjusting mechanism on light-weight, small-sized electronic devices, it is sufficient that the tapped member can be held by the screw rod by using a small amount of force. In this case, an electronic device can be sufficiently stably supported when the tapped member is provided so as to cover a part of the inner wall surface of the through hole.

In such height adjusting mechanisms, such as the height adjusting mechanism described in JP2007-173469A in which the tapped member is fixed only vertically to the fixing portion, when the tapped member is provided so as to cover a part of the inner wall surface of the through hole, the tapped member can easily be removed from the fixing portion because it is not fixed to the fixing portion in the radial direction of the through hole.

On the other hand, in height adjusting mechanism 1 according to the embodiment, as discussed above, because tapped member 2 is fixed to fixing portion 3a, also in the radial direction of through hole 3b, preventing tapped member 2 from being removed from fixing portion 3a also becomes possible. On this account, in the height adjusting mechanism according to the embodiment, also in the case of providing the tapped member so as to cover a part of the inner wall surface of the through hole, electronic devices can be stably supported. Accordingly, reducing the size of the tapped member becomes possible, and the entire weight of the electronic device and material and processing costs thus can be reduced.

Further, in height adjusting mechanism 1 according to this embodiment, tapped member 2 has engagement holes 22a, 22b, and 22c therein, and fixing portion 3a has projecting portions 13a, 13b, and 13c thereon. However, contrary to this, such a configuration is possible in which the tapped member has projecting portions and the fixing portion has engagement holes therein for engaging the projecting portions with the engagement holes.

Furthermore, in height adjusting mechanism 1, a single tapped member is provided that covers a part of the inner wall surface of the through hole formed in the fixing portion. However, a plurality of tapped members may be provided. Also, a single tapped member that covers the entire inner wall surface of the through hole may be provided.

Additionally, the material for forming the tapped member and the screw rod is not restricted to a metal material, which may be a resin material. Because the resin material generally has strength lower than that of the metal material, when the tapped member and the screw rod are made of a resin material, the force of the screw rod that is used to hold the tapped member is smaller than that in the case in which they are made of metal materials. However, the surface of the tapped member on which the thread groove is formed is widened, or a plurality of the tapped members are provided, as necessary, and consequently such configurations can be provided in which the screw rod sufficiently grips the tapped member. Also, the diameter of the screw rod or the thread ridge on the screw rod can be made larger, and a tapped member correspondingly adapted thereto is used to also enhance the strength of the screw rod to grip the tapped member.

### Second embodiment

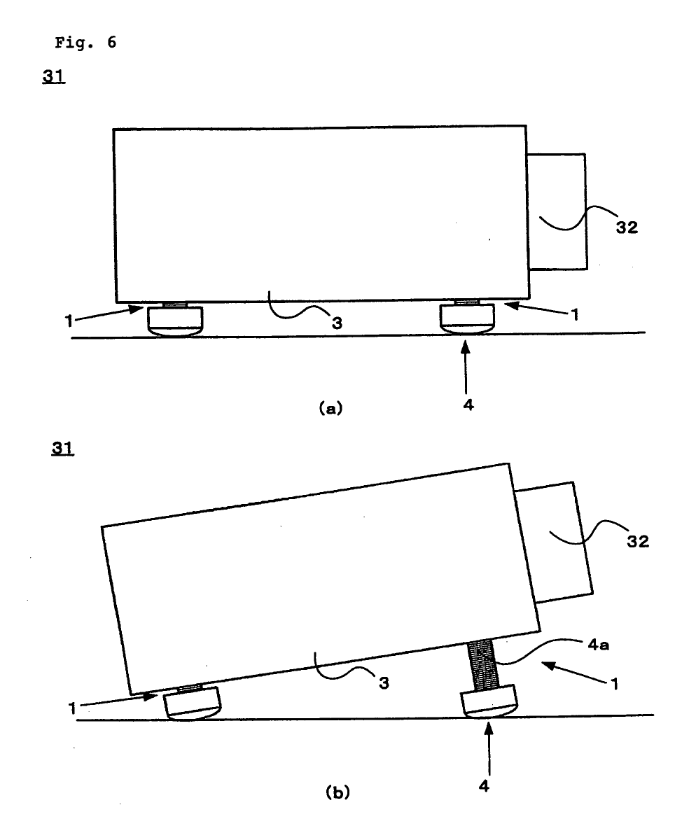

Next, an electronic device according to a second embodiment of the present invention will be described with reference to FIG. 6. FIG. 6 consists of side views depicting an electronic device according to a second embodiment of the present invention. In this embodiment, a projector, as an exemplary electronic device, is mounted with height adjusting mechanisms 1 according to the first embodiment. Projector 31 has projecting unit 32 on the front part for projecting video, and height adjusting mechanisms 1 at four corners on the bottom surface of housing 3.

In projector 31 shown in FIG. 6(a), the length of support legs 4 of four height adjusting mechanisms 1 extending from the bottom surface of housing 3 is equally varied so as to change the height of projector 31 to reach the surface on which the projector is placed.

Further, as shown in FIG. 6(b), not the length of rear support leg 4, but the length of front support leg 4, that extend from the bottom surface of housing 3, is varied to change the projection angle of projector 31.

In addition, projector 31 according to this embodiment has four height adjusting mechanisms 1. However, in addition to this, a variety of configurations can be provided including such configurations in which two height adjusting mechanisms 1 are provided on the front side and in which one is provided on the rear side and two on the front side.

1. A height adjusting mechanism, comprising:
a fixing portion having a through hole formed therein;
a tapped member having a thread groove formed thereon, wherein a rear side, which is the reverse side of a surface on which the thread groove is formed, covers at least a part of an inner wall surface of the through hole; and
a support leg having a screw rod formed with a thread ridge thereon in a longitudinal direction, the screw rod being inserted into the through hole such that the thread ridge is in engaging relation with the thread groove,
wherein the fixing portion and the tapped member are engaged with each other to cause the tapped member to be fixed to the fixing portion in a penetrating direction of the through hole and in a radial direction of the through hole.

2. The height adjusting mechanism according to claim 1, wherein the tapped member has an engagement portion extending toward the rear side, the engagement portion being in engaging relation with the fixing portion.

3. The height adjusting mechanism according to claim 2, wherein two of the engagement portions come into contact with two end portions of the fixing portion, respectively, in a penetrating direction of the through hole.

4. The height adjusting mechanism according to claim 2, wherein in the fixing portion and the engagement portion, the fixing portion is formed with a first projecting portion projecting in a penetrating direction of the through hole, and the engagement portion is formed with a first engagement hole with which the first projecting portion engages.

5. The height adjusting mechanism according to claim 1, wherein in the inner wall surface of the through hole and the rear side of the tapped member, the inner wall surface of the through hole is formed with a second projecting portion projecting in a radial direction of the through hole, and the rear side of the tapped member is formed with a second engagement hole with which the second projecting portion engages.

6. An electronic device comprising the height adjusting mechanism according to claim 1.

7. The height adjusting mechanism according to claim 3, wherein in the fixing portion and the engagement portion, the fixing portion is formed with a first projecting portion projecting in a penetrating direction of the through hole, and the engagement portion is formed with a first engagement hole with which the first projecting portion engages.

8. The height adjusting mechanism according to claim 2, wherein in the inner wall surface of the through hole and the rear side of the tapped member, the inner wall surface of the through hole is formed with a second projecting portion projecting in a radial direction of the through hole, and the rear side of the tapped member is formed with a second engagement hole with which the second projecting portion engages.

9. The height adjusting mechanism according to claim 3, wherein in the inner wall surface of the through hole and the rear side of the tapped member, the inner wall surface of the through hole is formed with a second projecting portion projecting in a radial direction of the through hole, and the rear side of the tapped member is formed with a second engagement hole with which the second projecting portion engages.

10. The height adjusting mechanism according to claim 4, wherein in the inner wall surface of the through hole and the rear side of the tapped member, the inner wall surface of the through hole is formed with a second projecting portion projecting in a radial direction of the through hole, and the rear side of the tapped member is formed with a second engagement hole with which the second projecting portion engages.

11. An electronic device comprising the height adjusting mechanism according to claim 2.

12. An electronic device comprising the height adjusting mechanism according to claim 3.

13. An electronic device comprising the height adjusting mechanism according to claim 4.

14. An electronic device comprising the height adjusting mechanism according to claim 5.
